(19) United States
(12) Patent Application Publication
(10) Pub. No.: US 2026/0371913 A1
(43) Pub. Date: Nov. 19, 2026

(54) METHOD FOR FORMING THIN FILM OF PEROVSKITE COMPOUND AND METHOD FOR MANUFACTURING SOLAR CELL USING SAME

(71) Applicant: JUSUNG ENGINEERING CO., LTD., Gwangju-si, Gyeonggi-do (KR)

(72) Inventors: Jae Ho KIM, Yongin-si, Gyeonggi-do (KR); Chul Joo HWANG, Yongin-si, Gyeonggi-do (KR)

(21) Appl. No.: 19/117,390

(22) PCT Filed: Aug. 25, 2023
(86) PCT No.: PCT/KR2023/012631

§ 371 Date: Mar. 31, 2025

(30) Foreign Application Priority Data
Oct. 7, 2022 (KR) 10-2022-0128677

(51) Int. Cl. H10K 71/10; H10K 30/57; H10K 85/50

(52) U.S. Cl. CPC H10K 71/10; H10K 30/57; H10K 85/50

(57) ABSTRACT

Provided are a method for forming a thin film of a perovskite compound and a method for manufacturing a solar cell using same, characterized by comprising: a process of supplying a precursor B into a chamber; a process of first supplying a precursor X into the chamber while maintaining power for plasma formation turned on; and a process of supplying a precursor A into the chamber, wherein the precursor B is formed of an organometallic compound comprising a divalent cation, the precursor X is formed of hydrogen halide, the precursor A is formed of at least one compound selected from amine-based compounds and amidine-based compounds, and the process of supplying the precursor A is performed after the process of supplying the precursor B and the process of first supplying the precursor X.

### TECHNICAL FIELD

The present inventive concept relates to a method of forming thin film of Perovskite compound and a method of manufacturing Solar Cell using the same.

### BACKGROUND ART

Conventionally, a solution process is mainly used in manufacturing solar cells using perovskite compound. The solution process is to apply a liquid perovskite compound on a substrate by dissolving a perovskite compound in a predetermined solvent by spin coating, spray coating, or slot die.

This solution process is not problematic when applying a perovskite compound to a substrate with a flat surface, but when a perovskite compound is applied to a crystalline silicon substrate with a pyramid structure to form a tandem solar cell, it is difficult to form a thin film with a uniform thickness.

### DISCLOSURE

### Technical Problem

The present inventive concept is devised to solve the above-described problem and is for providing a thin film formation method of perovskite compound using a deposition process, particularly atomic layer deposition, and a method of manufacturing solar cells using them.

### Technical Solution

To accomplish the above-described objects, an embodiment of the present inventive concept provides a method of forming a thin film of perovskite compound comprising a process of supplying B precursor in a chamber; a process of firstly supplying X precursor into the chamber; and a process of supplying A precursor into the chamber, wherein the B precursor includes an organic metal compound containing a divalent positive ion, the X precursor includes a hydrogen halide, and the A precursor includes at least one compound selected from the group consisting of an amine-based compound and an amidine-based compound, and wherein the process of supplying A precursor is performed after the process of supplying B precursor and the process of firstly supplying X precursor.

The process of supplying the B precursor may include a process of adsorbing the B precursor on a substrate, the process of firstly supplying X precursor may include forming an intermediate material made of a BXn (n<3) compound on the substrate by reacting the B precursor with the X precursor, the process of supplying A precursor may include a process of forming an ABXn (n<3) compound on the substrate by reacting the intermediate material made of a BXn (n<3) compound with the A precursor, and the A may include at least one monovalent organic positive ion selected from the group consisting of a monovalent organic positive ion of the amine-based compound and a monovalent organic positive ion of the amidine-based compound, the B may include the divalent positive ion, and the X may include a halogen compound.

The method of forming a thin film of perovskite compound may further comprise a purge process in at least one period among a period between the process of supplying B precursor and the process of firstly supplying X precursor, a period between the process of firstly supplying X precursor and the process of supplying A precursor, and a period after the process of supplying A precursor.

The method of forming a thin film of perovskite compound may further comprise a process of secondly supplying X precursor in the chamber after the process of supplying A precursor.

The process of secondly supplying X precursor into the chamber may include a process of applying power for plasma formation.

The method of forming a thin film of perovskite compound may further comprise a purge process in at least one period among a period between the process of supplying B precursor and the process of firstly supplying X precursor, a period between the process of firstly supplying X precursor and the process of supplying A precursor, a period between the process of supplying A precursor and the process of secondly supplying X precursor, and a period after the process of secondly supplying X precursor.

The process of supplying the B precursor may include a process of adsorbing the B precursor on a substrate, and wherein the process of firstly supplying X precursor may include forming a primary intermediate material made of a BXn (n<3) compound on the substrate by reacting the B precursor with the X precursor, wherein the process of supplying A precursor may include a process of forming a secondary intermediate material made of an ABXn (n<3) compound on the substrate by reacting the primary intermediate material made of a BXn (n<3) compound with the A precursor, wherein the process of secondly supplying X precursor may include a process of forming an ABX₃ compound on the substrate by reacting the secondary intermediate material made of an ABXn (n<3) compound with the X precursor, and wherein the A may include at least one monovalent organic positive ion selected from the group consisting of a monovalent organic positive ion of the amine-based compound and a monovalent organic positive ion of the amidine-based compound, the B may include the divalent positive ion, and the X may include a halogen compound.

The method of forming a thin film of perovskite compound may further comprise a process of supplying C precursor into the chamber in the process of supplying B precursor, wherein the C precursor may include at least one alkali metal-based compound.

The process of supplying the B precursor and the C precursor may include a process of adsorbing the B precursor and the C precursor on a substrate, and wherein the process of firstly supplying X precursor may include forming an intermediate material made of a CBXn (n<3) compound on the substrate by reacting the B precursor and the C precursor with the X precursor, wherein the process of supplying A precursor may include a process of forming an CABXn (n<3) compound on the substrate by reacting the intermediate material made of a CBXn (n<3) compound with the A precursor, and wherein the A may include at least one monovalent organic positive ion selected from the group consisting of a monovalent organic positive ion of the amine-based compound and a monovalent organic positive ion of the amidine-based compound, the B may include the divalent positive ion, the C may include an alkali metal, and the X may include a halogen compound.

The method of forming a thin film of perovskite compound may further comprise a process of supplying a crystal control material into the chamber between the process of firstly supplying X precursor and the process of supplying A precursor.

The crystal control material may include pyridine or pyridine derivative.

The process of firstly supplying X precursor into the chamber may include a process of applying power for plasma formation.

Another embodiment of the present inventive concept provides a method of forming a thin film of perovskite compound comprising a process of supplying B precursor and C precursor into a chamber; and a process of firstly supplying X precursor into the chamber, wherein the B precursor includes an organic metal compound containing a divalent positive ion, the C precursor includes at least one alkali metal-based compound, the X precursor includes a hydrogen halide, wherein the process of firstly supplying X precursor is performed after the process of supplying B precursor and C precursor.

Another embodiment of the present inventive concept provides a method of forming a thin film of perovskite compound comprising a process of supplying C precursor into a chamber; a process of supplying B precursor into the chamber; and a process of firstly supplying X precursor into the chamber, wherein the B precursor includes an organic metal compound containing a divalent positive ion, the C precursor includes at least one alkali metal-based compound, the X precursor includes a hydrogen halide, wherein the process of supplying C precursor is performed before the process of supplying B precursor and the process of firstly supplying X precursor.

Another embodiment of the present inventive concept provides a method of manufacturing a solar cell comprising forming a crystalline solar cell; forming a buffer layer on the crystalline solar cell; forming a perovskite solar cell on the buffer layer; and forming a first electrode on the perovskite solar cell and a second electrode on the crystalline solar cell, wherein the forming a perovskite solar cell comprises the method of forming a thin film of perovskite compound as above.

### Advantageous Effect

According to the present inventive concept, the following effects may be realized. According to an embodiment of the present inventive concept, since a perovskite compound is formed by atomic layer deposition, a tandem solar cell may be easily formed by applying the perovskite compound to a crystalline silicon substrate having a concave-convex structure.

According to an embodiment of the present inventive concept, the perovskite compound of ABX₃ may be easily prepared by performing A precursor supply process after B precursor supply process and X precursor supply process.

According to an embodiment of this inventive concept, since the A precursor supply process is performed after an intermediate material of BXn (n≤3) is formed, compound A of the A precursor is not exposed to a plasma, thereby, the intermediate material of BXn (n≤3) and the A precursor may react while the chemical bond of compound A of the A precursor is not broken.

According to an embodiment of this inventive concept, the X precursor is primarily supplied to form the primary intermediate material of the BXn (n<3) compound, the A precursor is supplied to form the secondary intermediate material of the ABXn (n<3) compound, and then the X precursor is secondarily supplied to form a thin film of the perovskite compound of ABX₃, thereby, the process conditions in a vacuum chamber can be adjusted more flexibly.

According to an embodiment of this inventive concept, when the power for plasma formation is maintained in an off state during the secondary supply process of the X precursor, it is possible to prevent the chemical bond of the compound A in the secondary intermediate material of the ABXn (n<3) from being broken.

### DESCRIPTION OF DRAWINGS

FIG. 1 is a flowchart illustrating a process of forming a thin film of a perovskite compound according to an embodiment of the present inventive concept.

FIG. 2 is a flowchart illustrating a process of forming a thin film of a perovskite compound according to another embodiment of the present inventive concept.

FIG. 3 is a flowchart illustrating a process of forming a thin film of a perovskite compound according to another embodiment of the present inventive concept.

FIG. 4 is a flowchart illustrating a process of forming a thin film of a perovskite compound according to another embodiment of the present inventive concept.

FIG. 5 is a flowchart illustrating a process of forming a thin film of a perovskite compound according to another embodiment of the present inventive concept.

FIG. 6 is a flowchart illustrating a process of forming a thin film of a perovskite compound according to another embodiment of the present inventive concept.

FIG. 7 is a flowchart illustrating a process of forming a thin film of a perovskite compound according to another embodiment of the present inventive concept.

FIG. 8 is a flowchart illustrating a process of forming a thin film of a perovskite compound according to another embodiment of the present inventive concept.

FIG. 9 is a flowchart illustrating a process of forming a thin film of a perovskite compound according to another embodiment of the present inventive concept.

FIG. 10 is a flowchart illustrating a process of forming a thin film of a perovskite compound according to another embodiment of the present inventive concept.

FIG. 11 is a flowchart illustrating a process of forming a thin film of a perovskite compound according to another embodiment of the present inventive concept.

FIG. 12 is a flowchart illustrating a process of forming a thin film of a perovskite compound according to another embodiment of the present inventive concept.

FIG. 13A is a graph showing the crystal properties of a thin film of a perovskite compound prepared according to an embodiment of the present inventive concept, and FIG. 13B is a graph showing the crystal properties of a thin film of a perovskite compound prepared according to another embodiment of the present inventive concept.

FIGS. 14A to 14E are process cross-sectional views illustrating a method of manufacturing a solar cell according to an embodiment of the present inventive concept.

### MODE FOR INVENTIVE CONCEPT

Advantages and features of the present inventive concept, and implementation methods thereof will be clarified through following embodiments described with reference to the accompanying drawings. The present inventive concept may, however, be embodied in different forms and should not be construed as limited to the embodiments set forth herein. Rather, these embodiments are provided so that this inventive concept will be thorough and complete, and will fully convey the scope of the present inventive concept to those skilled in the art. Furthermore, the present inventive concept is only defined by scopes of claims.

A shape, a size, a ratio, an angle, and a number disclosed in the drawings for describing embodiments of the present inventive concept are merely an example, and thus, the present inventive concept is not limited to the illustrated details. Like reference numerals refer to like elements throughout. In the following description, when the detailed description of the relevant known technology is determined to unnecessarily obscure the important point of the present inventive concept, the detailed description will be omitted. In a case where ‘comprise’, ‘have’, and ‘include’ described in the present specification are used, another part may be added unless ‘only~’ is used. The terms of a singular form may include plural forms unless referred to the contrary.

In construing an element, the element is construed as including an error range although there is no explicit description.

In describing a position relationship, for example, when a position relation between two parts is described as ‘on~’, ‘over~’, ‘under~’, and ‘next~’, one or more other parts may be disposed between the two parts unless ‘just’ or ‘direct’ is used.

In describing a time relationship, for example, when the temporal order is described as ‘after~’, ‘subsequent~’, ‘next~’, and ‘before~’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concept.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present inventive concept may be partially or overall coupled to or combined with each other, and may be variously inter-operated with each other and driven technically as those skilled in the art can sufficiently understand. The embodiments of the present inventive concept may be carried out independently from each other, or may be carried out together in co-dependent relationship.

Hereinafter, preferable embodiments of the present inventive concept will be described in detail with reference to the accompanying drawings.

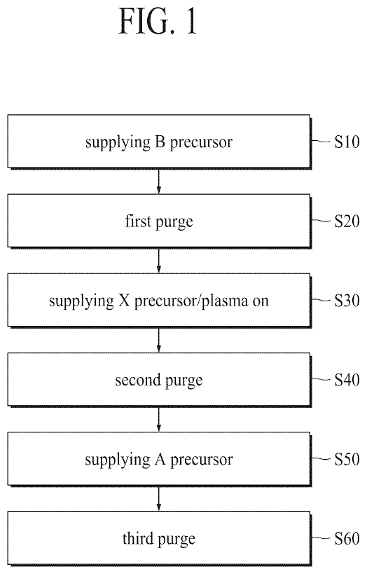

FIG. 1 is a flowchart illustrating a process of forming a thin film of a perovskite compound according to an embodiment of the present inventive concept.

As shown in FIG. 1, the thin film of the perovskite compound ABX₃ according to one embodiment of this inventive concept may be formed through atomic layer deposition (ALD) in a vacuum chamber, specifically, the atomic layer deposition (ALD) comprising a process of supplying B precursor S10, a first purge process S20, a process of supplying X precursor while maintaining power for plasma formation in on state S30, a second purge process S40, the process of supplying A precursor S50, and a third purge process S60.

The process of supplying the B precursor S10 includes a process of supplying the B precursor on a substrate while loading the substrate into the vacuum chamber to adsorb the B precursor on the substrate.

The B precursor may include organic metal compound containing a divalent positive ion, the B may include the divalent positive ion.

The organic metal compound containing the divalent positive ion may include metal selected from the group consisting of lead (Pb), tin (Sn), germanium (Ge), antimony (Sb), bismuth (Bi), and barium (Ba).

In detail, the organic metal compound containing the divalent positive ion may include a compound represented by the following Formula 1:

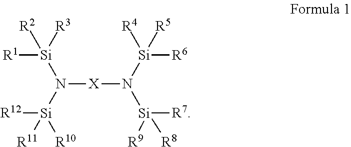

(In the Formula 1, each of R¹ to R¹² consists of hydrogen or an alkyl group independently, and X is selected from the group consisting of Pb, Sn, Ge, Sb, Bi, and Ba)

Alternatively, the organic metal compound containing the divalent positive ion may be selected from among the group consisting of Pb(CH₃)₄, Pb(C₂H₅)₄, Pb(SCN)₂, (C₂H₅)₃PbOCH₂C(CH₃)₃, Pb(C₁₁H₁₉O₂)₂, Pb((CH₃)₃C—COCHCO—C(CH₃)₃)₂, Pb((C₆H₅)₂PCH₂P(C₆H₅)₂)₂, Pb(N(CH₃)₂C(CH₃)₂OH)₂, and C₁₂H₂₈N₂O₂Pb.

The first purge process S20 may include a process of removing the B precursor remaining without being adsorbed on the substrate by supplying the first purge gas into the vacuum chamber.

The process of supplying the X precursor while maintaining the power for plasma formation in on state S30 may include a step of supplying the X precursor into the vacuum chamber to react the B precursor adsorbed on the substrate with the supplied X precursor to form an intermediate material of a BX₃ compound on the substrate.

The X precursor may include hydrogen halide, and X may include the halogen compound. The hydrogen halide may be selected from the group consisting of HI, HBr, HF, and HCl. In some cases, the X precursor may be supplied while maintaining the power for plasma formation in an off state rather than an on state. Power for plasma formation may be applied only for a part of the process period for supplying the X precursor.

The secondary purge process S40 may include a process of supplying a second purge gas into a vacuum chamber to remove the X precursor that does not react on the substrate and remains. The second purge gas may be the same as the first purge gas, but may be different in some cases.

The process of supplying the A precursor S50 may include a process of supplying the A precursor into the vacuum chamber to react the BX₃ compound formed on the substrate with the A precursor to form a thin film of a perovskite compound of an ABX₃ compound on the substrate.

The A precursor may include at least one compound selected from the group consisting of the amine-based compound and the amidine-based compound. The A may consist of the monovalent organic positive ion of the amine-based compound, the monovalent organic positive ion of the amidine-based compound, or the monovalent organic positive ion of the amine-based compound and the monovalent organic positive ion of the amidine-based compound. The A may have a structure where the monovalent organic positive ion of the amine-based compound is included therein at an x ratio and the monovalent organic positive ion of the amidine-based compound is included therein at a y ratio. In this case, each of x and y is greater than 0, and x+y=1.

The amine-based compound may be selected from the group consisting of methylamine, ethylamine, and phenethylamine. The amidine-based compound may consist of formamidine.

The third purge process S60 may include a process of removing the precursor A that does not react on the substrate by supplying a third purge gas into the vacuum chamber. The third purge gas may be the same as the first purge gas or the second purge gas, but may be different in some cases.

The precursor A, the precursor B, and the precursor X are made of materials that vaporize at a temperature in the range of room temperature to 200 °C, preferably at a temperature in the range of 50 °C to 150 °C. Accordingly, the process of manufacturing the ABX₃ perovskite compound can be performed through atomic layer deposition (ALD) at a temperature of 200 °C or less, preferably 150 °C or less. Thus, organic matter in the finally obtained ABX₃ compound can be prevented from being decomposed during the ALD process.

According to an embodiment of this inventive concept, the A precursor supply process S50 is performed after the B precursor supply process S10 and the X precursor supply process S30. Therefore, the perovskite compound of ABX₃ may be easily prepared by forming an intermediate material composed of a compound of BX₃ on the substrate first and then reacting the above BX₃ compound with the A precursor.

If the A precursor supply process S50 is performed before the B precursor supply process S10 so that an intermediate material made of a compound of AX₃ on the substrate is formed first and then the AX₃ compound and the B precursor are reacted, the ABX₃ perovskite compound cannot be easily obtained. This is because the reaction between the compound of AX₃ and the precursor B does not occur well.

In addition, if the A precursor supply process S50 is performed before the B precursor supply process S10 and then the process of supplying X precursor while maintaining power for plasma formation in on state S30 is performed, the chemical bond of the compound A in the A precursor made of organic material is broken by the plasma, so that the AX₃ intermediate material is not easily obtained and the final ABX₃ perovskite compound cannot be easily obtained.

On the other hand, according to an embodiment of this inventive concept, since the A precursor supply process S50 is performed after the BX₃ intermediate material is formed, the compound A in the A precursor is not exposed to plasma. Accordingly, the A precursor reacts with the ABX₃ perovskite compound while the chemical bond of compound A of the A precursor is not broken, thereby obtaining the final ABX₃ perovskite compound easily.

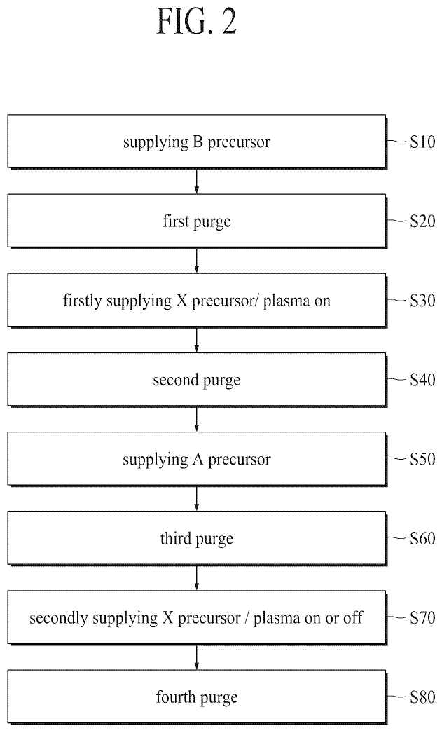

FIG. 2 is a flowchart illustrating a process of forming a thin film of a perovskite compound according to another embodiment of the present inventive concept.

As shown in FIG. 2, the thin film of the perovskite compound (ABX₃) according to another embodiment of this inventive concept may be formed through atomic layer deposition (ALD) in a vacuum chamber, specifically, the atomic layer deposition (ALD) comprising a process of supplying B precursor S10, a first purge process S20, a process of firstly supplying X precursor while maintaining power for plasma formation in on state S30, a second purge process S40, a process of supplying A precursor S50, a third purge process S60, a process of secondly supplying X precursor while maintaining power for plasma formation in on state or off state S70, and a fourth purge process S80.

Since the process of supplying the B precursor S10 and the first purge process S20 are the same as in FIG. 1, a repeated description thereof will be omitted.

The process of firstly supplying X precursor while maintaining power for plasma formation in on state S30 may include a process of forming a primary intermediate material made of a BXn (n<3) compound on the substrate by supplying the X precursor into the vacuum chamber and reacting the B precursor adsorbed on the substrate with the supplied X precursor.

Since the X precursor and the compound X are the same as those of FIG. 1, a repeated description thereof will be omitted.

Since the second purge process S40 is the same as that of FIG. 1, a repeated description thereof will be omitted.

The process of supplying the A precursor S50 may include a process of forming a secondary intermediate material made of an ABXn (n<3) compound on the substrate by supplying the A precursor into the vacuum chamber and reacting the BXn (n<3) compound formed on the substrate with the supplied A precursor.

Since the A precursor and the compound A are the same as those of FIG. 1 described above, a repeated description thereof will be omitted.

The third purge process S60 may include a process of removing the precursor A that does not react on the substrate by supplying a third purge gas into the vacuum chamber. The third purge gas may be the same as the first purge gas or the second purge gas, but may be different in some cases.

The process of secondly supplying X precursor while maintaining power for plasma formation in on state or off state S70 may include a process of forming a thin film of ABX₃ perovskite compound on the substrate by supplying the X precursor into the vacuum chamber and reacting the ABXn (n<3) compound formed on the substrate with the secondly supplied X precursor.

The X precursor in the process S70 may be the same as or different from the X precursor in the process S30.

The fourth purge process S80 may include a process of supplying a fourth purge gas into a vacuum chamber to remove the X precursor that does not react on the substrate and remains. The fourth purge gas may be the same as the first purge gas, the second purge gas, or the third purge gas, but may be different in some cases.

According to another embodiment of this inventive concept, the X precursor is firstly supplied to form the primary intermediate material of the BXn (n<3) compound, the A precursor is supplied to form the secondary intermediate material of the ABXn (n<3) compound, and then the X precursor is secondly supplied to form the thin film of the ABX₃ perovskite compound, thereby more flexibly controlling the process conditions in the vacuum chamber.

On the other hand, a secondary intermediate material made of ABXn (n<3) compound is formed on the substrate through the process of supplying the precursor A S50, and since the compound A made of the organic material chemically binds to the compounds B and X, the chemical bond in the compound A is not easily broken even when the power for plasma formation is in on state in the secondly supply process S70 of the X precursor. Therefore, it is possible to keep the power for plasma formation in on state during the secondly supply process S70 of the X precursor.

However, in order to prevent the chemical bond of the compound A from being broken in the second intermediate material made of the ABXn (n<3) compound during the secondly supply process S70 of the X precursor, it may be desirable to keep the power for plasma formation in off state during secondly supply process S70 of the X precursor.

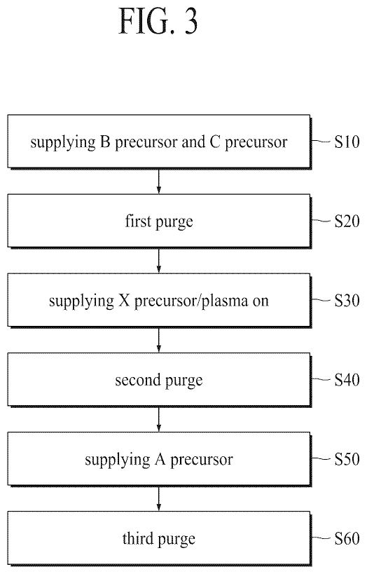

FIG. 3 is a flowchart illustrating a process of forming a thin film of a perovskite compound according to another embodiment of the present inventive concept.

As shown in FIG. 3, the thin film of the perovskite compound (ABX₃) according to another embodiment of this inventive concept may be formed through atomic layer deposition (ALD) in a vacuum chamber, specifically, the atomic layer deposition (ALD) comprising a process of supplying B precursor and C precursor S10, a first purge process S20, a process of firstly supplying X precursor while maintaining power for plasma formation in on state S30, a second purge process S40, a process of supplying A precursor S50, and a third purge process S60.

The process of supplying the B precursor and C precursor S10 includes a process of supplying the B precursor and C precursor on a substrate while loading the substrate into the vacuum chamber to adsorb the B precursor and C precursor on the substrate.

The B precursor and C precursor may be supplied simultaneously.

Since the B precursor and the compound B are the same as those of FIG. 1, a repeated description thereof will be omitted.

The C precursor may include at least one alkali metal-based compound. The compound C may include at least one alkali metal such as Cesium (Cs).

The alkali metal-based compound may include a compound represented by the following Formula 2:

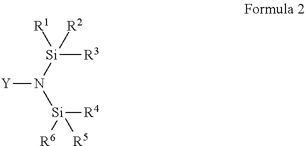

(In the Formula 2, each of R¹ to R⁶ consists of hydrogen or an alkyl group independently, and the Y is an alkali metal).

As described above, according to another embodiment of the present inventive concept, at least one alkali metal-based compound is added to a reactant, thereby compensating for instability of monovalent organic positive ion vulnerable to moisture, heat, and plasma.

The first purge process S20 may include a process of removing the B precursor and the C precursor remaining without being adsorbed on the substrate by supplying the first purge gas into the vacuum chamber.

The process of supplying the X precursor while maintaining the power for plasma formation in on state S30 may include a step of supplying the X precursor into the vacuum chamber to react the B precursor and the C precursor adsorbed on the substrate with the supplied X precursor to form an intermediate material of a CBX₃ compound on the substrate.

The X precursor and the compound X are the same as those of FIG. 1.

The second purge process S40 is the same as that of FIG. 1.

The process of supplying the A precursor S50 may include a process of supplying the A precursor into the vacuum chamber to react the CBX₃ compound formed on the substrate with the A precursor to form a thin film of a perovskite compound of an CABX₃ compound on the substrate.

The A precursor and the compound A are the same as those of FIG. 1.

The CA may have a structure where the monovalent organic positive ion of the amine-based compound is included therein at an x ratio, the monovalent organic positive ion of the amidine-based compound is included therein at a y ratio, and the monovalent positive ion of the alkali metal is included therein at a z ratio. In this case, each of x, y, and z is greater than 0, and x+y+z=1.

The third purge process S60 may include a process of removing the precursor A that does not react on the substrate by supplying a third purge gas into the vacuum chamber. The third purge gas may be the same as the first purge gas or the second purge gas, but may be different in some cases.

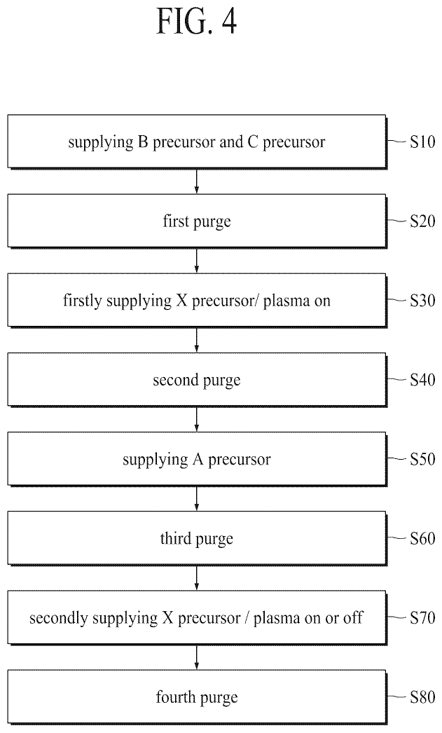

FIG. 4 is a flowchart illustrating a process of forming a thin film of a perovskite compound according to another embodiment of the present inventive concept.

As shown in FIG. 4, the thin film of the perovskite compound (ABX₃) according to another embodiment of this inventive concept may be formed through atomic layer deposition (ALD) in a vacuum chamber, specifically, the atomic layer deposition (ALD) comprising a process of supplying B precursor and C precursor S10, a first purge process S20, a process of firstly supplying X precursor while maintaining power for plasma formation in on state S30, a second purge process S40, a process of supplying A precursor S50, a third purge process S60, a process of secondly supplying X precursor while maintaining power for plasma formation in on state or off state S70, and a fourth purge process S80.

Since the process of supplying the B precursor and the C precursor S10 and the first purge process S20 are the same as in FIG. 3, a repeated description thereof will be omitted.

The process of firstly supplying X precursor while maintaining power for plasma formation in on state S30 may include a process of forming a primary intermediate material made of a CBXn (n<3) compound on the substrate by supplying the X precursor into the vacuum chamber and reacting the B precursor and the C precursor adsorbed on the substrate with the supplied X precursor.

Since the X precursor and the compound X are the same as those of FIG. 3, a repeated description thereof will be omitted.

Since the second purge process S40 is the same as that of FIG. 3, a repeated description thereof will be omitted.

The process of supplying the A precursor S50 may include a process of forming a secondary intermediate material made of an CABXn (n<3) compound on the substrate by supplying the A precursor into the vacuum chamber and reacting the CBXn (n<3) compound formed on the substrate with the supplied A precursor.

Since the A precursor and the compound A are the same as those of FIG. 3 described above, a repeated description thereof will be omitted.

The third purge process S60 may include a process of removing the precursor A that does not react on the substrate by supplying a third purge gas into the vacuum chamber. The third purge gas may be the same as the first purge gas or the second purge gas, but may be different in some cases.

The process of secondly supplying X precursor while maintaining power for plasma formation in on state or off state S70 may include a process of forming a thin film of CABX₃ perovskite compound on the substrate by supplying the X precursor into the vacuum chamber and reacting the CABXn (n<3) compound formed on the substrate with the secondly supplied X precursor.

The X precursor in the process S70 may be the same as or different from the X precursor in the process S30.

The fourth purge process S80 may include a process of supplying a fourth purge gas into a vacuum chamber to remove the X precursor that does not react on the substrate and remains. The fourth purge gas may be the same as the first purge gas, the second purge gas, or the third purge gas, but may be different in some cases.

According to another embodiment of this inventive concept, the X precursor is firstly supplied to form the primary intermediate material of the CBXn (n<3) compound, the A precursor is supplied to form the secondary intermediate material of the CABXn (n<3) compound, and then the X precursor is secondly supplied to form the thin film of the CABX₃ perovskite compound, thereby more flexibly controlling the process conditions in the vacuum chamber.

On the other hand, a secondary intermediate material made of CABXn (n<3) compound is formed on the substrate through the process of supplying the precursor A S50, and since the compound A made of the organic material chemically binds to the compounds C, B and X, the chemical bond in the compound A is not easily broken even when the power for plasma formation is in on state in the secondly supply process S70 of the X precursor. Therefore, it is possible to keep the power for plasma formation in on state during the secondly supply process S70 of the X precursor.

However, in order to prevent the chemical bond of the compound A from being broken in the second intermediate material made of the CABXn (n<3) compound during the secondly supply process S70 of the X precursor, it may be desirable to keep the power for plasma formation in off state during secondly supply process S70 of the X precursor.

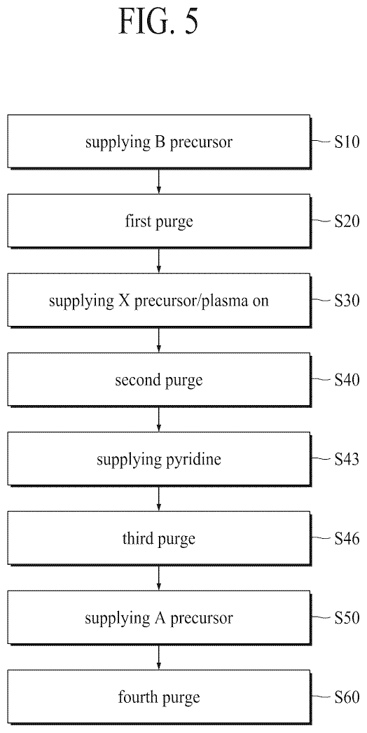

FIG. 5 is a flowchart illustrating a process of forming a thin film of a perovskite compound according to another embodiment of the present inventive concept.

FIG. 5 is different from FIG. 1 described above in that a process of supplying pyridine S43 and a third purge process S46 are additionally performed between the second purge process S40 and the process of supplying A precursor S50.

According to another embodiment of the present inventive concept, the crystal properties of the finally obtained ABX₃ compound may be improved by supplying pyridine or a pyridine derivative to an intermediate material made of a BX₃ compound and then supplying a precursor A. Within the following specification, pyridine or pyridine derivative is collectively referred to as pyridine.

The pyridine derivative can include, but is not limited to, 4-methyl pyridine or 4-tertbutyl pyridine.

In addition to the pyridine, a crystal control material or growth control material of a perovskite compound of an ABX₃ compound may be additionally supplied. The crystal control material or growth control material may improve crystal stability by removing dangling bonds in the crystal through a passivation effect.

In FIG. 5, the third purge process S46 may include a process of removing the pyridine or pyridine derivative remaining on the substrate by supplying a third purge gas into the vacuum chamber. Meanwhile, in FIG. 5, since the third purge process S46 is added, the purge process performed after the process of supplying A precursor S50 becomes the fourth purge process S60.

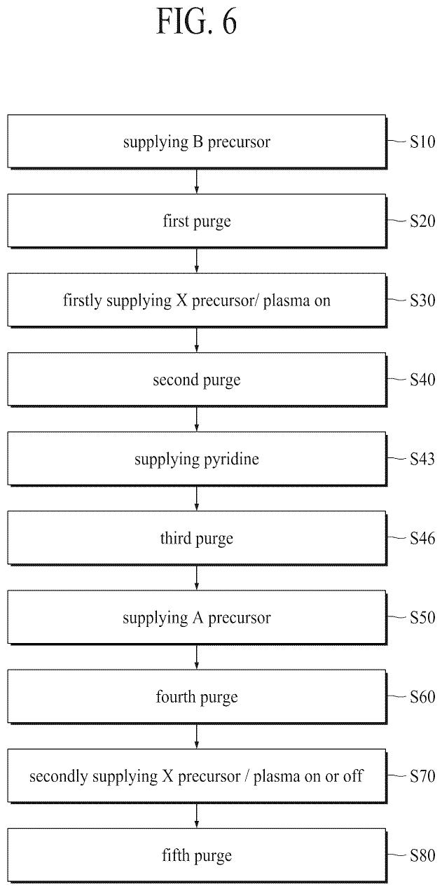

FIG. 6 is a flowchart illustrating a process of forming a thin film of a perovskite compound according to another embodiment of the present inventive concept.

FIG. 6 is different from FIG. 2 described above in that a process of supplying pyridine S43 and a third purge process S46 are additionally performed between the second purge process S40 and the process of supplying A precursor S50.

In FIG. 6, the third purge process S46 may include a process of removing the pyridine or pyridine derivative remaining on the substrate by supplying a third purge gas into the vacuum chamber.

Meanwhile, in FIG. 6, since the third purge process S46 is added, the purge process performed after the process of supplying A precursor S50 becomes the fourth purge process S60, and the purge process performed after the process of secondly supplying X precursor while maintaining power for plasma formation in on state or off state S70 becomes the fifth purge process S80.

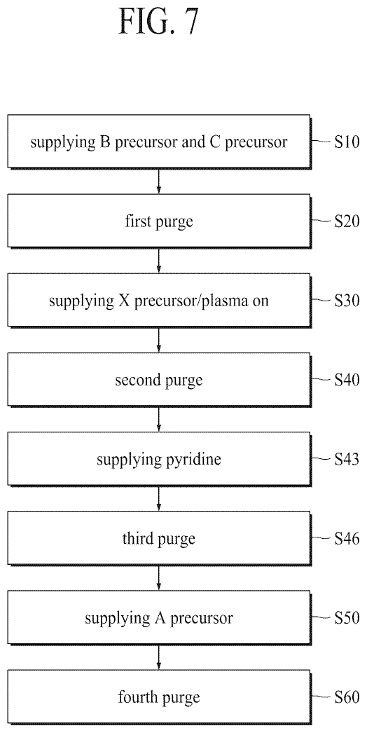

FIG. 7 is a flowchart illustrating a process of forming a thin film of a perovskite compound according to another embodiment of the present inventive concept.

FIG. 7 is different from FIG. 3 described above in that a process of supplying pyridine S43 and a third purge process S46 are additionally performed between the second purge process S40 and the process of supplying A precursor S50.

In FIG. 7, the third purge process S46 may include a process of removing the pyridine or pyridine derivative remaining on the substrate by supplying a third purge gas into the vacuum chamber.

Meanwhile, in FIG. 7, since the third purge process S46 is added, the purge process performed after the process of supplying A precursor S50 becomes the fourth purge process S60.

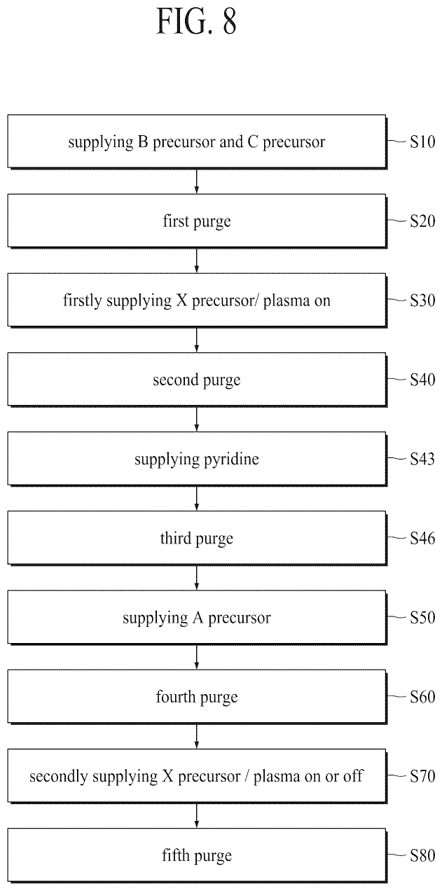

FIG. 8 is a flowchart illustrating a process of forming a thin film of a perovskite compound according to another embodiment of the present inventive concept.

FIG. 8 is different from FIG. 4 described above in that a process of supplying pyridine S43 and a third purge process S46 are additionally performed between the second purge process S40 and the process of supplying A precursor S50.

In FIG. 8, the third purge process S46 may include a process of removing the pyridine or pyridine derivative remaining on the substrate by supplying a third purge gas into the vacuum chamber.

Meanwhile, in FIG. 8, since the third purge process S46 is added, the purge process performed after the process of supplying A precursor S50 becomes the fourth purge process S60, and the purge process performed after the process of secondly supplying X precursor while maintaining power for plasma formation in on state or off state S70 becomes the fifth purge process S80.

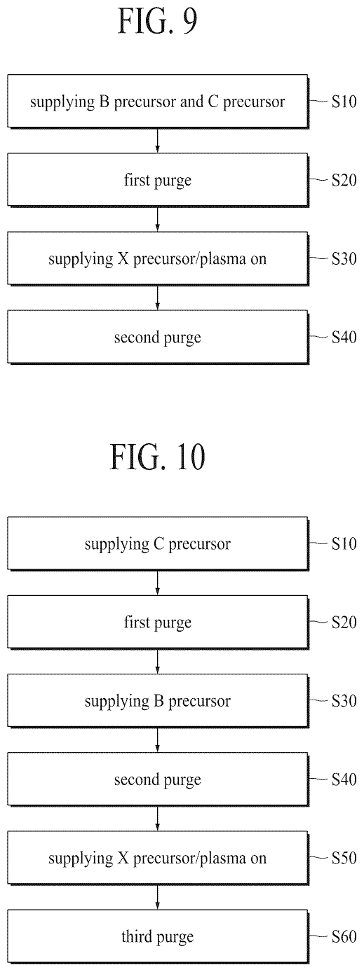

FIG. 9 is a flowchart illustrating a process of forming a thin film of a perovskite compound according to another embodiment of the present inventive concept.

As shown in FIG. 9, the thin film of the perovskite compound (CBX₃) according to another embodiment of this inventive concept may be formed through atomic layer deposition (ALD) in a vacuum chamber, specifically, the atomic layer deposition (ALD) comprising a process of supplying B precursor and C precursor S10, a first purge process S20, a process of firstly supplying X precursor while maintaining power for plasma formation in on state S30 and a second purge process S40.

Since each process is the same as described above, a repeated description will be omitted. The same is true of the following embodiments.

FIG. 10 is a flowchart illustrating a process of forming a thin film of a perovskite compound according to an embodiment of the present inventive concept.

As shown in FIG. 10, the thin film of the perovskite compound CBX₃ according to one embodiment of this inventive concept may be formed through atomic layer deposition (ALD) in a vacuum chamber, specifically, the atomic layer deposition (ALD) comprising a process of supplying C precursor S10, a first purge process S20, a process of supplying B precursor S30, a second purge process S40, a process of supplying X precursor while maintaining power for plasma formation in on state S50, and a third purge process S60.

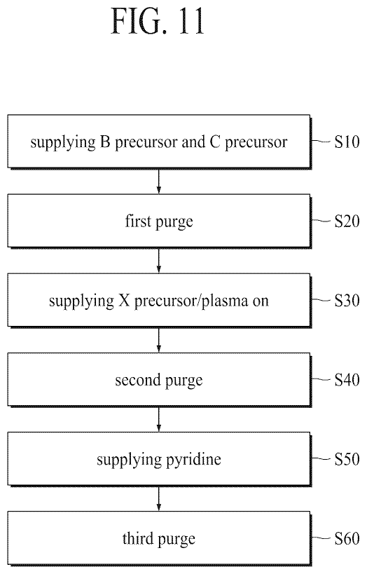

FIG. 11 is a flowchart illustrating a process of forming a thin film of a perovskite compound according to an embodiment of the present inventive concept.

As shown in FIG. 11, the thin film of the perovskite compound CBX₃ according to one embodiment of this inventive concept may be formed through atomic layer deposition (ALD) in a vacuum chamber, specifically, the atomic layer deposition (ALD) comprising a process of supplying B precursor and C precursor S10, a first purge process S20, a process of supplying X precursor while maintaining power for plasma formation in on state S30, a second purge process S40, a process of supplying pyridine S50 and a third purge process S60.

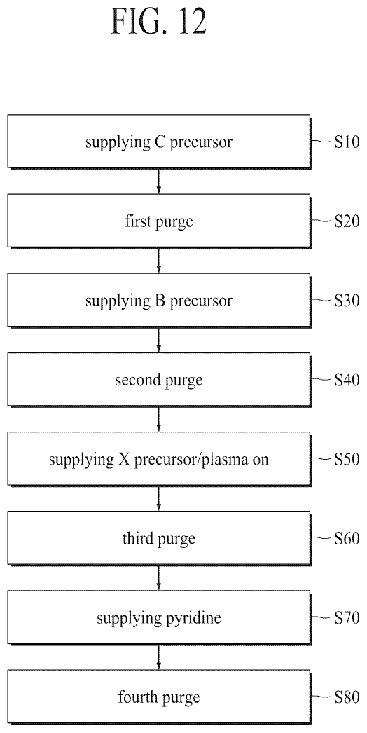

FIG. 12 is a flowchart illustrating a process of forming a thin film of a perovskite compound according to an embodiment of the present inventive concept.

As shown in FIG. 12, the thin film of the perovskite compound CBX₃ according to one embodiment of this inventive concept may be formed through atomic layer deposition (ALD) in a vacuum chamber, specifically, the atomic layer deposition (ALD) comprising a process of supplying C precursor S10, a first purge process S20, a process of supplying B precursor S30, a second purge process S40, a process of supplying X precursor while maintaining power for plasma formation in on state S50, a third purge process S60, a process of supplying pyridine S70 and a fourth purge process S80.

The embodiments of FIGS. 9 to 12 may further include a process of supplying the X precursor while maintaining power for plasma formation in on state or off state after each purge process, and a subsequent purge process.

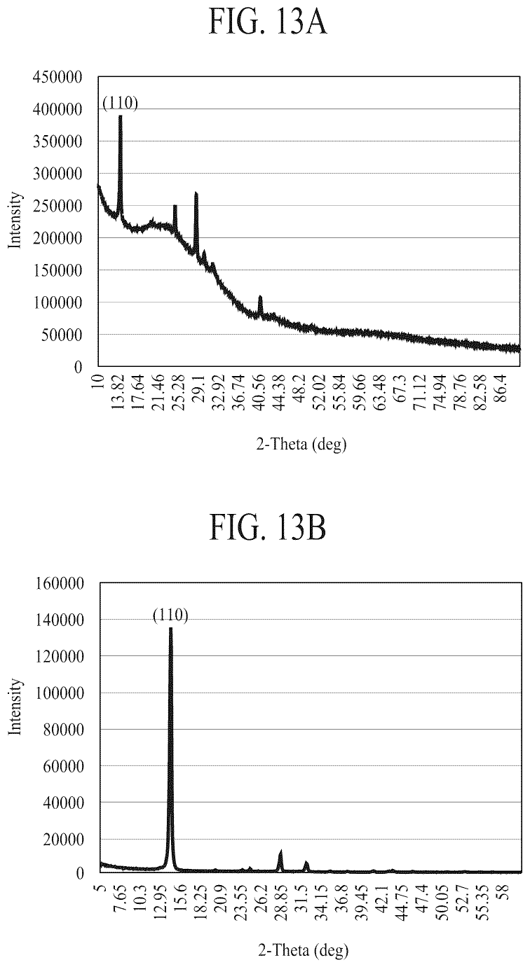

FIG. 13A is a graph showing the crystal properties of a thin film of a perovskite compound prepared according to an embodiment of the present inventive concept, and FIG. 13B is a graph showing the crystal properties of a thin film of a perovskite compound prepared according to another embodiment of the present inventive concept.

In FIGS. 13A and 13B, the X-axis represents the angle at which the beam is irradiated, and the Y-axis represents the size of the crystal.

In particular, FIG. 13A is a graph showing the crystal properties of the thin film of the perovskite compound prepared by the process according to FIG. 2, and FIG. 13B is a graph showing the crystal properties of the thin film of the perovskite compound prepared by the process according to FIG. 6.

Specifically, FIG. 13A shows the crystal properties of the perovskite compound of MAPbI₃ prepared by supplying Pb(C₂H₅)₄ as a B precursor, performing first purge, firstly supplying HI as the X precursor while maintaining power for plasma formation in on state to form PbI₂ on the substrate, performing second purge, supplying methylamine (MA) as the A precursor to forms MAPbI₂ on the substrate, performing third purge, secondly supplying HI as the X precursor while maintaining power for plasma formation in on state to form MAPbI₃ on the substrate, and performing fourth purge.

FIG. 13B shows the crystal properties of the perovskite compound of MAPbI₃ prepared by supplying Pb(C₂H₅)₄ as a B precursor, performing first purge, firstly supplying HI as the X precursor while maintaining power for plasma formation in on state to form PbI₂ on the substrate, performing second purge, supplying pyridine, performing third purge, supplying methylamine (MA) as the A precursor to forms MAPbI₂ on the substrate, performing fourth purge, secondly supplying HI as the X precursor while maintaining power for plasma formation in on state to form MAPbI₃ on the substrate, and performing fifth purge.

In the case of the perovskite compound prepared according to FIG. 13A, the direction 110 which is the crystal growth direction is a main peak, but the additional peak grows, so that the characteristics in which the crystal growth directions are aligned in one direction are somewhat reduced and the characteristics of amorphous characteristics are shown in the range of 10° to 40°.

On the other hand, in the case of the perovskite compound prepared according to FIG. 13B, the crystal growth direction 110 is a main peak and the additional peak hardly grows, indicating that the characteristic in which the crystal growth direction is aligned in one direction are improved.

Particularly, in FIG. 13B, the peak is formed large, which means that the crystal is formed large. When the crystal is formed large in this way, the occurrence of loss between the crystal and the crystal is small and the electrical conductivity is excellent.

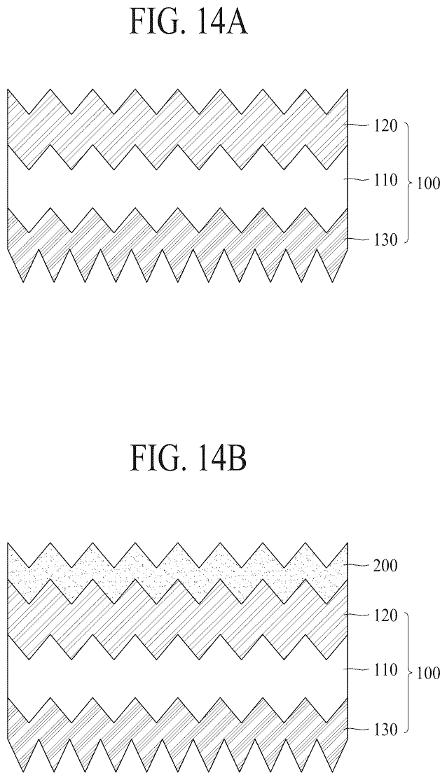

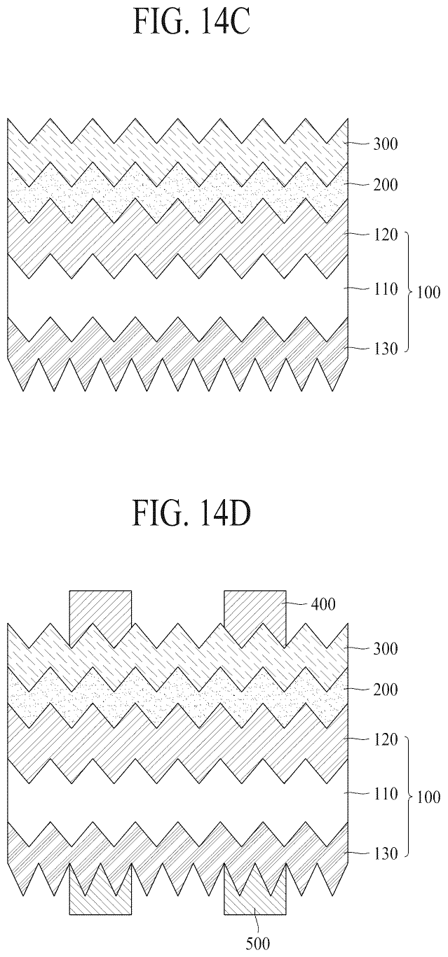

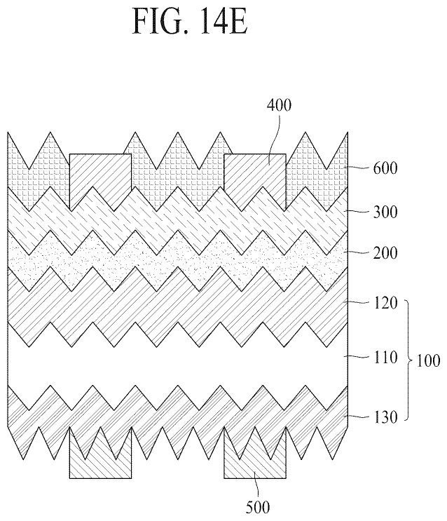

FIGS. 14A to 14E are process cross-sectional views illustrating a method of manufacturing a solar cell according to an embodiment of the present inventive concept.

First, as seen in FIG. 14A, a crystalline solar cell 100 is manufactured.

The crystalline solar cell 100 is manufactured through a process of etching one surface and the other surface of a semiconductor substrate 110 such as a wafer to form a concave-convex structure, doping a specific dopant on the one surface of the semiconductor substrate 110 to form a first semiconductor layer 120, and doping a specific dopant on the other surface of the semiconductor substrate 110 to form a second semiconductor layer 130.

As one surface and the other surface of the semiconductor substrate 110 are formed in the concave-convex structure, the first semiconductor layer 120 and the second semiconductor layer 130 are formed in a shape corresponding to the concave-convex structure.

On the other hand, the drawing shows that both one surface and the other surface of the semiconductor substrate 110 are formed in the concave-convex structure, but it is not necessarily limited to it. One surface of the semiconductor substrate 110 may be formed in the concave-convex structure and the other surface may be formed in a flat structure. Or, the other surface of the semiconductor substrate 110 may be formed in the concave-convex structure and one surface may be formed in a flat structure. In some cases, one surface and the other surface of the semiconductor substrate 110 may be formed in a flat structure.

The semiconductor substrate 110 may be formed of the P-type or N-type wafer, the first semiconductor layer 120 may be doped with a dopant having a polarity different from that of the semiconductor substrate 110, and the second semiconductor layer 130 may be doped with a dopant having the same polarity as that of the semiconductor substrate 110. For example, the semiconductor substrate 110 may be made of a P-type wafer, the first semiconductor layer 120 may be doped with an N-type dopant, and the second semiconductor layer 130 may be doped with a P-type dopant to form a P+ layer.

Although not shown, an I-type semiconductor layer may be additionally formed between the semiconductor substrate 110 and the first semiconductor layer 120, and between the semiconductor substrate 110 and the second semiconductor layer 130.

Next, as seen in FIG. 14B, a buffer layer 200 is formed on the crystalline solar cell 100.

The buffer layer 200 is formed on the first semiconductor layer 120. As the first semiconductor layer 120 is formed in a concave-convex structure, the buffer layer 200 is formed in a shape corresponding to the concave-convex structure.

The buffer layer 200 is provided between the crystalline solar cell 100 and a below-described perovskite solar cell 300, and thus, a solar cell according to an embodiment of the present inventive concept has a structure of a tandem solar cell on the basis of a tunnel junction.

It is preferable that the buffer layer 200 includes a material for enabling light having a long wavelength, passing through the perovskite solar cell 300, to be incident on the crystalline solar cell 100 without being lost. For example, the buffer layer 200 may be formed of a transparent conductive oxide, a carbonaceous conductive material, a metallic material, or a conductive polymer, and in some cases, an n-type or p-type dopant may be doped with the material.

Next, as seen in FIG. 14C, a perovskite solar cell 300 is formed on the buffer layer 200. As the buffer layer 200 is formed in a concave-convex structure, the perovskite solar cell 300 may also be formed in a concave-convex structure.

The perovskite solar cell 300 may include a first conductive charge transfer layer provided on the buffer layer 200, a light absorption layer provided on the first conductive charge transfer layer, and a second conductive charge transfer layer provided on the light absorption layer.

The first conductive charge transfer layer may be formed of an electron transfer layer and the second conductive charge transfer layer may be formed of a hole transfer layer. Or, the first conductive charge transfer layer may be formed of a hole transfer layer and the second conductive charge transfer layer may be formed of an electron transfer layer.

The electron transporting layer may include an N-type organic material, such as bathocuproine (BCP), C60, or phenyl-C61-butyric acid methyl ester (PCBM), various N-type metal oxides such as ZnO, c-TiO₂/mp-TiO₂, SnO₂, or IZO known to those skilled in the art, and a compound including various N-type organic or inorganic materials.

The hole transporting layer may include various p-type organic materials such as Spiro-MeO-TAD, Spiro-TTB, polyaniline, polyphenol, poly(3,4-ethylenedioxythiophene)-poly(styrenesulfonate) (PEDOT-PSS), poly[bis(4-phenyl)(2,4,6-trimethylphenyl)amine] (PTAA), and poly(3-hexylthiophene-2,5-diyl) (P3HT) known to those skilled in the art, various P-type metal oxides such as Ni oxide, Mo oxide, V oxide, W oxide, or Cu oxide known to those skilled in the art, and a compound including various P-type organic or inorganic materials.

The light-absorbing layer comprises the thin film of the aforementioned perovskite compound, and therefore, a repeated description of the light-absorbing layer will be omitted.

Next, as shown in FIG. 14D, a first electrode 400 is formed on a top surface of the perovskite solar cell 300, and a second electrode 500 is formed on a bottom surface of the crystalline solar cell 100.

Since the first electrode 400 is formed on an incident surface where sunlight is incident, the first electrode 400 is patterned in a predetermined shape. The second electrode 500 may also be configured to allow reflected light of sunlight to enter the solar cell by forming a pattern in a predetermined shape, but is not limited thereto.

Next, as shown in FIG. 14E, a passivation layer 600 is formed on the first electrode 400. In this case, a part of the passivation layer 600 is etched so that the first electrode 400 may be exposed.

As the perovskite solar cell 300 is formed in a concave-convex structure, the passivation layer 600 may also be formed in a concave-convex structure. The passivation layer 600 may be formed of various materials such as SiO, SiON, SiN, Al₂O₃, or MgF. In particular, the passivation layer 600 may be made of polydimethylsiloxane, and when the polydimethylsiloxane is formed on the perovskite solar cell 300, a micro-pyramidal concave-convex structure may be obtained.

Hereinabove, the embodiments of the present inventive concept have been described in more detail with reference to the accompanying drawings, but the present inventive concept is not limited to the embodiments and may be variously modified within a range which does not depart from the technical spirit of the present inventive concept. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. A method of forming a thin film of perovskite compound comprising:
a process of supplying a B precursor into a chamber;
a process of firstly supplying an X precursor into the chamber; and
a process of supplying an A precursor into the chamber,
wherein the B precursor includes an organic metal compound containing a divalent positive ion, the X precursor includes a hydrogen halide, and the A precursor includes at least one compound selected from a group consisting of an amine-based compound and an amidine-based compound, and
wherein the process of supplying the A precursor is performed after the process of supplying the B precursor and the process of firstly supplying the X precursor.

2. The method of forming a thin film of perovskite compound of claim 1, wherein the process of supplying the B precursor includes a process of adsorbing the B precursor on a substrate, and
wherein the process of firstly supplying the X precursor includes forming an intermediate material made of a BXn (n<3) compound on the substrate by reacting the B precursor with the X precursor,
wherein the process of supplying the A precursor includes a process of forming an ABXn (n<3) compound on the substrate by reacting the intermediate material made of the BXn (n<3) compound with the A precursor, and
wherein the A includes at least one monovalent organic positive ion selected from a group consisting of a monovalent organic positive ion of the amine-based compound and a monovalent organic positive ion of the amidine-based compound, the B includes the divalent positive ion, and the X includes a halogen compound.

3. The method of forming a thin film of perovskite compound of claim 1, further comprising a purge process in at least one period among a period between the process of supplying the B precursor and the process of firstly supplying the X precursor, a period between the process of firstly supplying the X precursor and the process of supplying the A precursor, and a period after the process of supplying the A precursor.

4. The method of forming a thin film of perovskite compound of claim 1, further comprising a process of secondly supplying the X precursor into the chamber after the process of supplying the A precursor.

5. The method of forming a thin film of perovskite compound of claim 4, wherein the process of secondly supplying the X precursor into the chamber includes a process of applying power for plasma formation.

6. The method of forming a thin film of perovskite compound of claim 4, further comprising a purge process in at least one period among a period between the process of supplying the B precursor and the process of firstly supplying the X precursor, a period between the process of firstly supplying the X precursor and the process of supplying the A precursor, a period between the process of supplying the A precursor and the process of secondly supplying the X precursor, and a period after the process of secondly supplying the X precursor.

7. The method of forming a thin film of perovskite compound of claim 4, wherein the process of supplying the B precursor includes a process of adsorbing the B precursor on a substrate, and
wherein the process of firstly supplying the X precursor includes forming a primary intermediate material made of a BXn (n<3) compound on the substrate by reacting the B precursor with the X precursor,
wherein the process of supplying the A precursor includes a process of forming a secondary intermediate material made of an ABXn (n<3) compound on the substrate by reacting the primary intermediate material made of the BXn (n<3) compound with the A precursor,
wherein the process of secondly supplying the X precursor includes a process of forming an ABX₃ compound on the substrate by reacting the secondary intermediate material made of the ABXn (n<3) compound with the X precursor, and
wherein the A includes at least one monovalent organic positive ion selected from the group consisting of a monovalent organic positive ion of the amine-based compound and a monovalent organic positive ion of the amidine-based compound, the B includes the divalent positive ion, and the X includes a halogen compound.

8. The method of forming a thin film of perovskite compound of claim 1, further comprising a process of supplying the C precursor into the chamber in the process of supplying the B precursor,
wherein the C precursor includes at least one alkali metal-based compound.

9. The method of forming a thin film of perovskite compound of claim 8, wherein the process of supplying the B precursor and the C precursor includes a process of adsorbing the B precursor and the C precursor on a substrate, and
wherein the process of firstly supplying the X precursor includes forming an intermediate material made of a CBXn (n<3) compound on the substrate by reacting the B precursor and the C precursor with the X precursor,
wherein the process of supplying the A precursor includes a process of forming an CABXn (n<3) compound on the substrate by reacting the intermediate material made of the CBXn (n<3) compound with the A precursor, and
wherein the A includes at least one monovalent organic positive ion selected from the group consisting of a monovalent organic positive ion of the amine-based compound and a monovalent organic positive ion of the amidine-based compound, the B includes the divalent positive ion, the C includes an alkali metal, and the X includes a halogen compound.

10. The method of forming a thin film of perovskite compound of claim 1, further comprising a process of supplying a crystal control material into the chamber between the process of firstly supplying the X precursor and the process of supplying A precursor.

11. The method of forming a thin film of perovskite compound of claim 10, wherein the crystal control material includes pyridine or pyridine derivative.

12. The method of forming a thin film of perovskite compound of claim 1, wherein the process of firstly supplying the X precursor into the chamber includes a process of applying power for plasma formation.

13. A method of forming a thin film of perovskite compound comprising:
a process of supplying a B precursor and a C precursor into a chamber; and
a process of firstly supplying an X precursor into the chamber,
wherein the B precursor includes an organic metal compound containing a divalent positive ion, the C precursor includes at least one alkali metal-based compound, the X precursor includes a hydrogen halide,
wherein the process of firstly supplying the X precursor is performed after the process of supplying B precursor and C precursor.

14. A method of forming a thin film of perovskite compound comprising:
a process of supplying a C precursor into a chamber;
a process of supplying a B precursor into the chamber; and
a process of firstly supplying an X precursor into the chamber,
wherein the B precursor includes an organic metal compound containing a divalent positive ion, the C precursor includes at least one alkali metal-based compound, the X precursor includes a hydrogen halide,
wherein the process of supplying the C precursor is performed before the process of supplying B precursor and the process of firstly supplying X precursor.

15. A method of manufacturing a solar cell comprising:
forming a crystalline solar cell;
forming a buffer layer on the crystalline solar cell;
forming a perovskite solar cell on the buffer layer; and
forming a first electrode on the perovskite solar cell and a second electrode on the crystalline solar cell,
wherein the forming the perovskite solar cell comprises the method of forming a thin film of perovskite compound of claim 1.
